(19) United States
(12) Patent Application Publication
(10) Pub. No.: US 2008/0174264 A1
(43) Pub. Date: Jul. 24, 2008

(54) Information processing terminal and display control method

(75) Inventor: Ryuta Nomoto, Osaka (JP)

Correspondence Address: KRATZ, QUINTOS & HANSON, LLP, 1420 K Street, N.W., Suite 400, WASHINGTON, DC, 20005, US

(73) Assignee: SANYO ELECTRIC CO. LTD., Moriguchi-shi (JP)

(21) Appl. No.: 12/007,868

(22) Filed: Jan. 16, 2008

(30) Foreign Application Priority Data
Jan. 18, 2007 (JP) 2007-009214

(51) Int. Cl. H02J 7/00; G01R 31/36

(52) U.S. Cl. 320/106

(57) ABSTRACT

An information processing terminal improves user convenience by more accurately displaying a remaining charge of a battery installed. The battery is any one of a plurality of batteries differing in chargeable capacity. The mobile phone has a battery-type judging unit that reads a signal output from a battery-type output unit of the battery and judges which of two types of batteries differing in chargeable capacity is installed. A voltage measuring unit measures the output voltage of a cell unit. A threshold setting unit acquires thresholds corresponding to the judged battery type and a judging unit judges, using the thresholds, a battery icon to be displayed. A battery icon for a large-capacity battery includes four battery bars at maximum. A battery icon for a normal-capacity battery includes three battery bars at maximum. A display, generating unit causes a display unit to display the battery icon according to the judgment.

This application is based on an application No. 2007-009214, filed in Japan, the content of which is hereby incorporated by reference.

### BACKGROUND OF THE INVENTION

(1) Field of the Invention

The present invention relates to an information processing terminal that displays a remaining battery charge.

(2) Description of the Related Art

Information processing terminals, including mobile phones, display on the display screen an icon representing a remaining charge of a battery installed therein. The icon provides a user of the information processing terminal with an indication of the remaining time before the information processing terminal becomes unusable because of exhaustion of the battery. The types of batteries usable on such an information processing terminal include an alkaline battery and a lithium-ion battery. Generally, such an information processing terminal identifies the type of a battery installed therein and displays, on an LCD (Liquid Crystal Display), information regarding the remaining battery charge in a format corresponding to the identified battery type. With this function, the information processing terminal is enabled to display the remaining battery charge closely and accurately, on condition that the installed battery is of a specific type that the information processing terminal is capable of sensing the remaining battery charge with sufficient accuracy, as compared with the case where the installed battery is of another type that the information processing terminal is not capable of precisely sensing the remaining battery charge.

It should be noted, however, that batteries of the same type (such as lithium-ion batteries) include batteries that are different in chargeable capacity. That is, some batteries are larger in chargeable capacity than batteries that are normally used on an information processing terminal. Even if such a large-size battery is installed, the information processing terminal presents the same display as what is presented when a normal-size battery is installed, regardless of the difference in chargeable capacity. That is to say, the user of the information processing terminal is unable to distinguish whether the battery currently installed is a normal-size battery or a battery of a different size.

### SUMMARY OF THE INVENTION

The present invention provides an information processing terminal that displays an icon indicating a remaining charge of a battery installed therein. The information processing terminal includes: a judging unit operable to judge a type of the battery installed, out of a plurality of types of batteries differing in chargeable capacity; and a display control unit operable to cause a display unit to display the icon for the battery installed, the icon visually representing the difference in chargeable capacity among the plurality of types of batteries.

### BRIEF DESCRIPTION OF THE DRAWINGS

These and the other objects, advantages and features of the invention will become apparent from the following description thereof taken in conjunction with the accompanying drawings which illustrate a specific embodiment of the invention.

In the drawings:

FIG. 1 is a view showing an external representation of a mobile phone according to an embodiment of the present invention;

FIG. 2 is a block diagram schematically showing a structure of the mobile phone;

FIGS. 3A and 3B are views each showing a structure of data stored in a storage unit;

FIG. 4 is a flowchart of processing steps performed to display a state of a battery;

FIG. 5 is a view schematically showing a relation between a battery voltage and the number of battery bars displayed with respect to a discharge time, according to the embodiment;

FIG. 6 is a view schematically showing a relation between a battery voltage and the number of battery bars displayed with respect to a discharge time, according to a modification of the present invention;

FIGS. 7A and 7B are views each showing an example of a battery icon according to the embodiment;

FIGS. 8A and 8B are views each showing an example of a battery icon according to a modification of the present invention; and

FIGS. 9A and 9B are views each showing an example of a battery icon having battery bars of varying size correspondingly to a remaining battery charge.

### DESCRIPTION OF THE PREFERRED EMBODIMENT

The following describes a mobile phone 1, which is an information processing terminal according to one embodiment of the present invention.

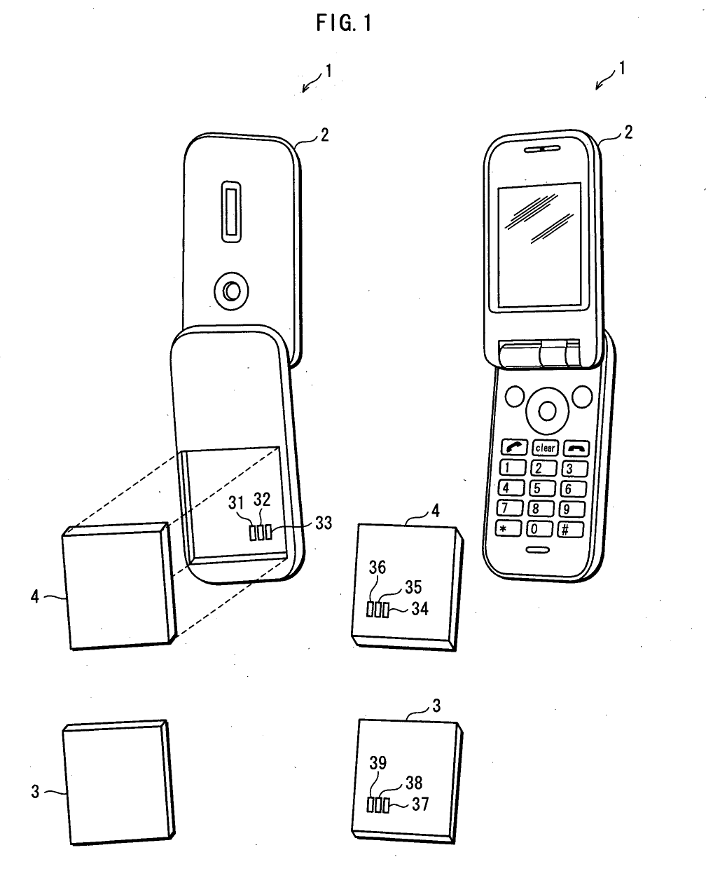

As illustrated in FIG. 1, the mobile phone 1 according to the embodiment of the present invention operates on either of a battery 3 or 4 being installed in a main body 2 of the mobile phone 1.

The battery 4 is a so-called a large battery and has a larger chargeable capacity than the battery 3, which is a normal battery. Naturally, the battery 4 is usable for longer hours than the battery 3 without recharging.

The mobile phone 1 selectively displays one of two different battery icons on a display screen of the mobile phone 1, according to the type of the battery currently installed. The battery icon indicates an estimate of the remaining battery time.

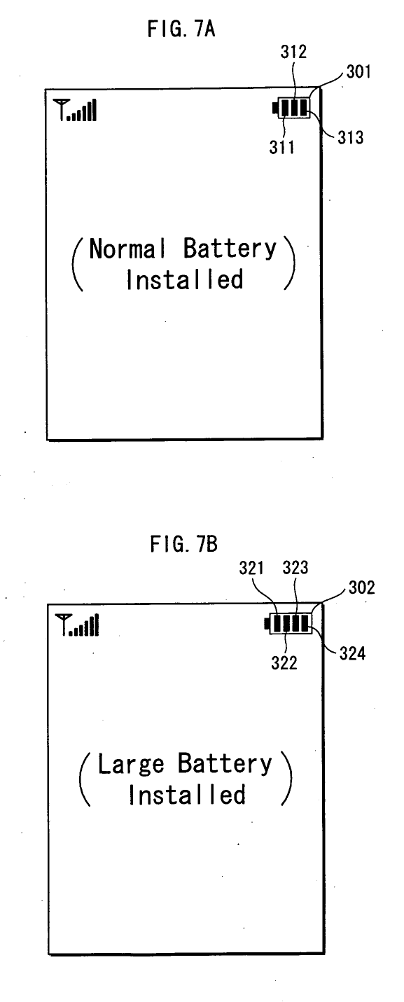

More specifically, the mobile phone 1 displays a battery icon 301 shown in FIG. 7A in the case where the battery 3 is installed, and displays a battery icon 302 shown in FIG. 7B in the case where the battery 4 is installed.

The battery icon 301 includes three battery bars 311-313, whereas the battery icon 302 includes four battery bars 321-324.

In the case of the battery icon 301, the maximum number of battery bars that can be concurrently displayed is three. The number of battery bars on display decreases one by one with decrease in remaining battery charge. In the case of the battery icon 302, the maximum number of battery bars that can be concurrently displayed is four. Similarly to the battery icon 301, the number of battery bars on display decreases one by one with decrease in remaining battery charge.

Consequently, if the battery icon presented on the display screen is the battery icon 302, which encloses a space that is large enough to display four battery bars therein, a user of the mobile phone 1 is enabled to recognize that the battery 4 is installed. On the other hand, if the battery icon presented on the display screen is the battery icon 301, which encloses a space that is large enough to display only three battery bars therein, the user is enabled to recognize that the battery 3 is installed.

The following describes a case where the battery 4, which is a large battery, is used with the mobile phone 1 according to the embodiment of the present invention.

### <Structure>

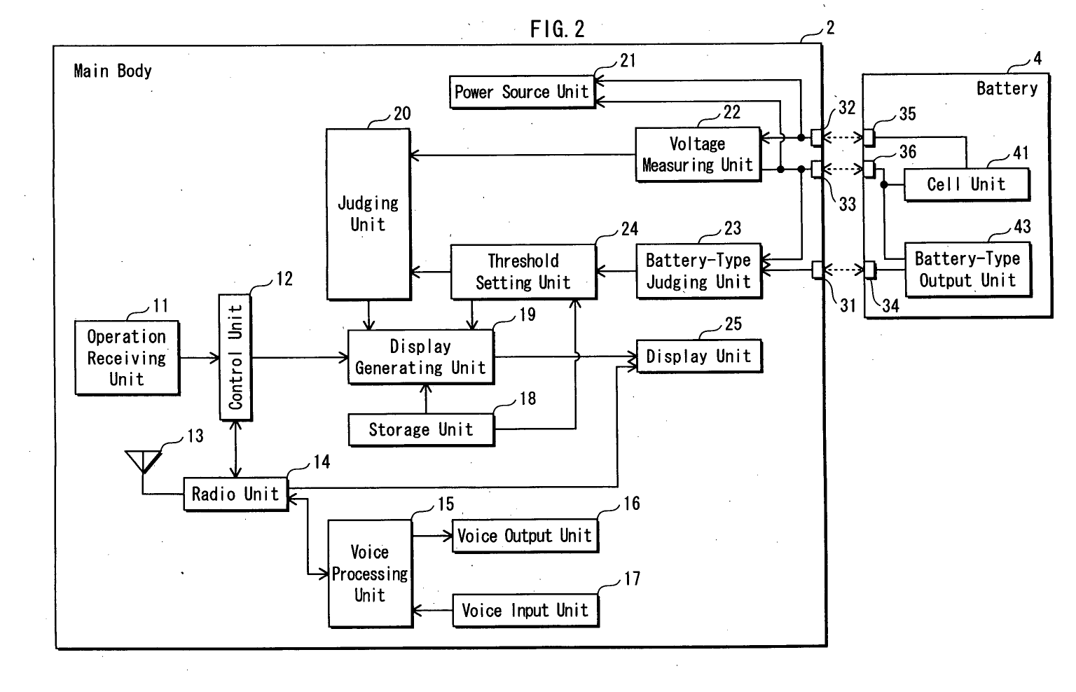

As illustrated in FIG. 2, the mobile phone 1 includes the main body 2 and the battery 4. Physically, the mobile phone 1 is a computer system composed generally of a microprocessor, ROM, RAM, a display unit, a keypad, a radio communication unit, and an antenna. The RAM stores a computer program. The mobile phone 1 achieves its functionally by the microprocessor executing the computer program.

As illustrated in FIG. 2, the battery 4 includes a cell unit 41, a battery-type output unit 43, and terminals 34-36.

When installed into the main body 2, the battery 4 is engaged into electrical connection with the main body 2. Under this state, the terminal 34 that is connected to a voltage line indicating a battery status makes contact with a terminal 31 of the main body 2. The terminal 35 that is connected to a power-source line makes contact with a terminal 32 of the main body 2. The terminal that is connected to a ground line makes contact with a terminal 33 of the main body 2.

The battery-type output unit 43 outputs via the terminal 34 a high-level potential (3.3 volts, for example) indicating that the battery currently installed therein is a large battery and outputs a ground potential via the terminal 36.

The ground line connected at one end to the terminal 36 is connected at the other end to the cell unit 41. In addition, the power-source line is connected to the terminal 35 as stated above. When a battery charger (not illustrated) is connected to the cell unit 41 via the terminals 35 and 36, the cell unit 41 is recharged. When the cell unit 41 is connected to the main body 2 via the terminals 35 and 36, the cell unit 41 supplies power to the main body 2.

The battery 3 is identical in structure to the battery 4, except for the following differences. The first difference is that the cell unit 41 of the battery 3 is smaller in chargeable capacity than the cell unit 41 of the battery 4. The second difference is that the battery-type output unit 43 of the battery 3 outputs a low-level potential indicating a normal battery.

As illustrated in FIG. 2, the main body 2 includes an operation receiving unit 11, a control unit 12, an antenna 13, a radio unit 14, a voice processing unit 15, a voice output unit 16, a voice input unit 17, a storage unit 18, a display generating unit 19, a judging unit 20, a power source unit 21, a voltage measuring unit 22, a battery-type judging unit 23, a threshold setting unit 24, a display unit 25, and the terminals 31-33.

The operation receiving unit 11 is provided with a keypad and a control circuit (not illustrated) similarly to a common mobile phone. The keypad includes various keys that are necessary to place a call. For example, an on-hook key, an off-hook key, and a ten-key used to input a telephone number are included. The control circuit detects a push of individual keys and transmits an instruction corresponding to the pushed key to the control unit 12.

The control unit 12 includes a CPU and control software for the CPU. In response to an instruction received from the operation receiving unit 11, the control unit 12 controls overall operation of the mobile phone 1.

The radio unit 14 communicates with a base station (not illustrated) by radio via the antenna 13 to conduct telephone calls and data communications. More specifically, the radio unit 14 receives a radio signal from the base station, demodulates the received signal into a baseband signal, and outputs the baseband signal to the voice processing unit 15. In reverse, the radio unit 14 modulates a baseband signal received from the voice processing unit 15 and transmits the baseband signal to the base station via the antenna 13. The voice output unit 16 acts as a speaker that outputs amplified sound according to a voice signal.

The voice input unit 17 also acts as a microphone that converts voice input into a voice signal and outputs the voice signal to the voice processing unit 15.

The voice processing unit 15 receives a baseband signal from the radio unit 14, converts the baseband signal into a voice signal, and outputs the voice signal to the voice output unit 16. In addition, the voice processing unit 15 receives a voice signal from the voice input unit 17, converts the voice signal into a baseband signal, and outputs the baseband signal to the radio unit 14.

A ground line connected at one end to the power source unit 21 is connected at the other end to the terminal 33. In addition, the power-source line connected at one end to the terminal 36 of the battery 4 is connected at the other end to the terminal 32. The power source unit 21 receives power supplied from the cell unit 41 via the terminals 32 and 33 and in turn supplies power to other components of the main body 2 that require power supply.

The voltage measuring unit 22 measures a source voltage supplied from the cell unit 41 via the terminals 32 and terminal 33. The voltage measuring unit 22 then outputs the measured voltage value as a battery voltage to the judging unit 20.

A ground line connected at one end to the battery-type judging unit 23 is connected at the other end to the terminal 33. In addition, a voltage line for receiving an input of battery status is connected at one end to the battery-type judging unit 23 and to the terminal 31 at the other end. With the above-described configuration, the battery-type judging unit 23 first detects whether an output voltage of the battery-type output unit 43 is at a high level or a low level. If the detection result indicates a high-level, the battery-type judging unit 23 judges that the type of the battery installed is a large battery. Consequently, the battery-type judging unit 23 outputs a value indicating that the battery installed is a large battery (the value “1” in this example), to the threshold setting unit 24. On the other hand, if the detection result indicates a low-level, the battery-type judging unit 23 judges that the type of the battery installed is a normal battery. Consequently, the battery-type judging unit 23 outputs a value indicating that the battery installed is a normal battery (the value “0” in this case), to the threshold setting unit 24.

The threshold setting unit 24 reads, from the storage unit 18, one of threshold counts and one of threshold groups both corresponding to the value received from the battery-type judging unit 23. Note that the threshold counts and the threshold groups will be described later in detail. The threshold setting unit 24 then outputs the read threshold count and threshold group to the judging unit 20. More specifically, if the received value is “0”, the threshold setting unit 24 reads a threshold count A1 and a threshold group A2 from the storage unit 18 and outputs the threshold count A1 and the threshold group A2 to the judging unit 20. On the other hand, if the received value is “1”, the threshold setting unit 24 reads a threshold count B1 and a threshold group B2 from the storage unit 18 and outputs the threshold count B1 and the threshold group B2 to the judging unit 20.

The judging unit 20 determines the number of battery bars to be displayed, based on the battery voltage received from the voltage measuring unit 22 as well as on the threshold count and the threshold group both selected by the threshold setting unit 24.

The following describes the threshold counts and the threshold groups, along with its data structure when stored in the storage unit 18. Note that a threshold count indicates the total number of thresholds included in a corresponding threshold group.

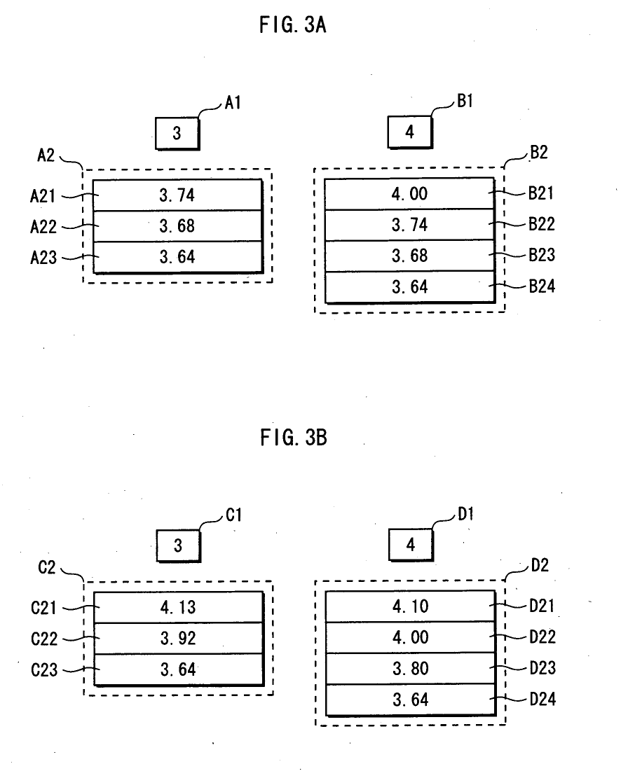

As shown in FIG. 3A, the storage unit 18 stores the threshold count A1 and the threshold group A2 as well as the threshold count B1 and the threshold group B2. The threshold count A1 and the threshold group A2 correspond to a normal battery, whereas the threshold count B1 and the threshold group B correspond to a large battery.

The threshold group A2 includes as many thresholds as the threshold count A1 (three, in this embodiment), namely a threshold A21, a threshold A22, and a threshold A23. Similarly, the threshold group B2 includes as many thresholds as the threshold count B1 (four, in this embodiment), namely a threshold B21, a threshold B22, a threshold B23, and a threshold B24.

The threshold count is equal to the maximum number of battery bars to be displayed as part of a corresponding battery icon.

The thresholds are used in a judgment process performed to determine the number of battery bars to be displayed according to the battery voltage. More specifically, when the battery voltage is equal to the threshold A21 (3.74 volts, in this embodiment) or higher, the number of battery bars to be displayed is equal to the total number of thresholds (=threshold count A1). When the battery voltage is equal to the threshold A22 (3.68 volts, in this embodiment) or higher, the number of battery bars to be displayed is equal to the number obtained by subtracting “1” from the total number of thresholds (=threshold count A1−1). In a similar manner, when the battery voltage is equal to the threshold A23 (3.64 volts, in this embodiment), the number of battery bars to be displayed is equal to the number obtained by subtracting “2” from the total number of thresholds (=the threshold count A1−2).

Now, the description goes back to the judging unit 20.

The judging unit 20 acquires a corresponding one of the threshold counts and a corresponding one of the threshold groups from the threshold setting unit 24 and assigns the acquired threshold count into a variable i. In addition, the judging unit 20 receives the battery voltage from the voltage measuring unit 22 and conducts the following process (a).

(a) The judging unit 20 selects a largest one of the thresholds from the acquired threshold group and conducts the following process (b).

Suppose, for example, the threshold group B2 includes the threshold B21 holding the value “4.00”, the threshold B22 holding the value “3.742”, the threshold B23 holding the value “3.68”, and the threshold B24 holding the value “3.64”. In this case, the judging unit 20 first selects the threshold B21, which is the largest threshold value of all.

(b) The judging unit 20 compares the battery voltage with the selected threshold. When the threshold is less than the battery voltage, the following process (c) is performed. On the other hand, when the threshold is equal to the battery voltage or larger, the following process (d) is performed.

(c) The judging unit 20 informs the display generating unit 19 about the value of the variable i as the number of battery bars to be displayed. The judging unit 20 then terminates the process.

(d) The judging unit 20 decrements the variable i by “1” and then judges whether or not the variable i is equal to “0”. If the variable i is equal to “0”, the judging unit 20 informs the display generating unit 19 about the value “0” as the number of battery bars to be displayed. The judging unit 20 then terminates the process. On the other hand, if the variable i is not equal to “0”, the judging unit 20 selects, from the threshold group, the second largest threshold next to the threshold used in the previous judgment and conducts the process (b) described above.

The display generating unit 19 receives panel information from the control unit 12. The panel information represents a display screen to be presented on the display unit 25. In addition, the display generating unit 19 outputs a signal representing the display screen indicated by the panel information to the display unit 25. As a result, the display unit 25 displays the display screen.

The display generating unit 19 causes the display unit 25 to display a standby screen and an antenna level. In addition, the display generating unit 19 receives, from the judging unit 20, information indicating the number of battery bars to be displayed and causes the display unit 25 to display the battery icon according to the received information.

In order to cause the display unit 25 to display the battery icon, the display generating unit 19 outputs to the display unit 25 a signal representing an image shown in FIG. 7B, for example.

The battery icon 302 encloses a space that is large enough to display four battery bars, and as many battery bars as the value of the variable i is displayed in the battery icon 302. For example, when the variable i holds the value “3”, three battery bars, namely the battery bars 322, 323, and 324, are displayed but the battery bar 321 is not displayed. Instead of the battery bar 321, a space that is large enough to display the battery bar 321 is left blank in the battery icon 302.

The display unit 25 is a liquid crystal display that receives red-, green-, and blue-color output signals as well as horizontal and vertical sync signals from the display generating unit 19. The display unit 25 displays images according to the received signals.

### <Operation>

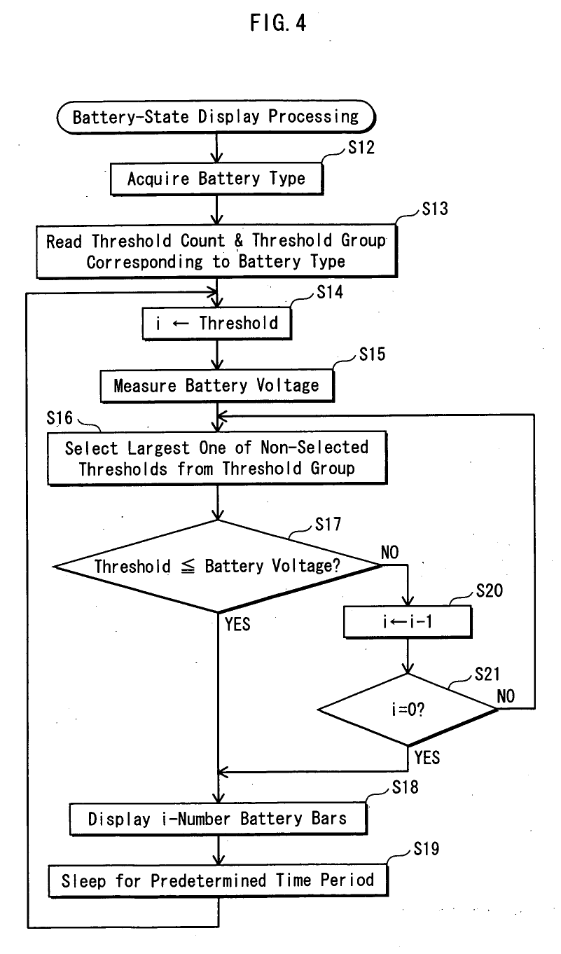

The following describes the processing steps performed by the mobile phone 1 to display the battery state, with reference to the flowchart shown in FIG. 4.

First of all, a user of the mobile phone 1 installs the battery 4 into the main body 2. As a result, the power source unit 21 is electrically connected to the cell unit 41, so that the cell unit 41 supplies power to the power source unit 21. In addition, the battery-type judging unit 23 is electrically connected to the battery-type output unit 43.

The battery-type judging unit 23 judges whether the output voltage of the battery-type output unit 43 is at a high level or a low level. If the output voltage is at a high-level, the battery-type judging unit 23 outputs the value “1” to the threshold setting unit 24. On the other hand, if the output voltage is at a low-level, the battery-type judging unit 23 outputs the value “0” to the threshold setting unit 24 (Step S12).

The threshold setting unit 24 reads, from the storage unit 18, one of the threshold counts and one of the threshold groups both corresponding to the value acquired from the battery-type judging unit 23 (Step S13) and outputs the read threshold count and threshold group to the judging unit 20. More specifically, if the acquired value is “1”, the threshold setting unit 24 reads the threshold count B1 and the threshold group B2. On the other hand, if the acquired value is “0”, the threshold setting unit 24 reads the threshold count A1 and the threshold group A2. In this case, the threshold setting unit 24 therefore reads the threshold count B1 and the threshold group B2.

The judging unit 20 acquires the threshold count and the threshold group from the threshold setting unit 24 and assigns the value of the acquired threshold count to the variable i (Step S14).

Next, the voltage measuring unit 22 measures the battery voltage supplied by the cell unit 41 and outputs the measured value of battery voltage to the judging unit 20 (Step S15).

The judging unit 20 selects one of the thresholds from the acquired threshold group in descending order (Step S16).

The threshold group B2 includes the threshold B21 which holds the value “4.00”, the threshold B22 which holds the value “3.74”, and the threshold B23 which holds the value “3.68”, and the threshold B24 which holds the value “3.64”. Thus, the judging unit 20 selects the threshold B21, which holds the largest value when Step S16 is performed for the first time.

Next, the judging unit 20 compares the battery voltage with the selected threshold (Step S17). If the threshold is smaller than the battery voltage (Step S17: NO), the display control unit 19 causes the battery state to be displayed using as many battery bars as the value of variable i (Step S18).

The battery state is displayed by presenting the battery icon 302 shown as an example in FIG. 7B.

The battery icon 302 encloses a space that is large enough to display four battery bars, and as many battery bars as the value of the variable i are displayed in the space. For example, if the variable i holds the value “3”, three battery bars, namely the battery bars 322, 323, and 324, are displayed but the battery bar 321 is not displayed. Instead of the battery bar 321, a space that is large enough to display the battery bar 321 is left blank in the battery icon 302.

Next, after a sleep of a predetermined time period (Step S19), the processing goes back to Step S14. Note that Step S19 is optional and may be omitted.

If the judgment in Step S17 results in that the threshold is equal to the battery voltage or higher (Step S17: YES), the judging unit 20 decrements the variable i by “1” (Step S20) and then judges whether the variable i is equal to “0” or not (Step S21). If the variable i is equal to “0” (Step S21: YES), Step S18 is performed next. If the variable i is not equal to “0” (Step S21: NO), Step S16 is performed next.

As described above, the mobile phone 1 displays an icon that visually represents the difference in chargeable capacity among a plurality of types of batteries. Display of such an icon allows the user to immediately know which type of battery is currently installed in the mobile phone 1. In addition, display of such an icon allows the user to readily and accurately estimate the remaining battery time, with consideration given to the chargeable capacity that differs depending on the battery type. With these advantages, the mobile phone 1 improves user convenience.

### <Supplemental Note>

Up to this point, the present invention has been described by way of the above embodiment. It should be naturally appreciated, however, that the present invention is not limited to the specific embodiment described above and various modifications including the following may be made without departing from the gist of the present invention.

### (1) Modification of Threshold Setting

Various modifications may be made to the above embodiment regarding how to set the threshold count A1 and the thresholds A21-A23 for a normal battery as well as the threshold count B1 and the thresholds B21-B24 for a large battery.

First of all, the following describes the threshold setting according to the above embodiment.

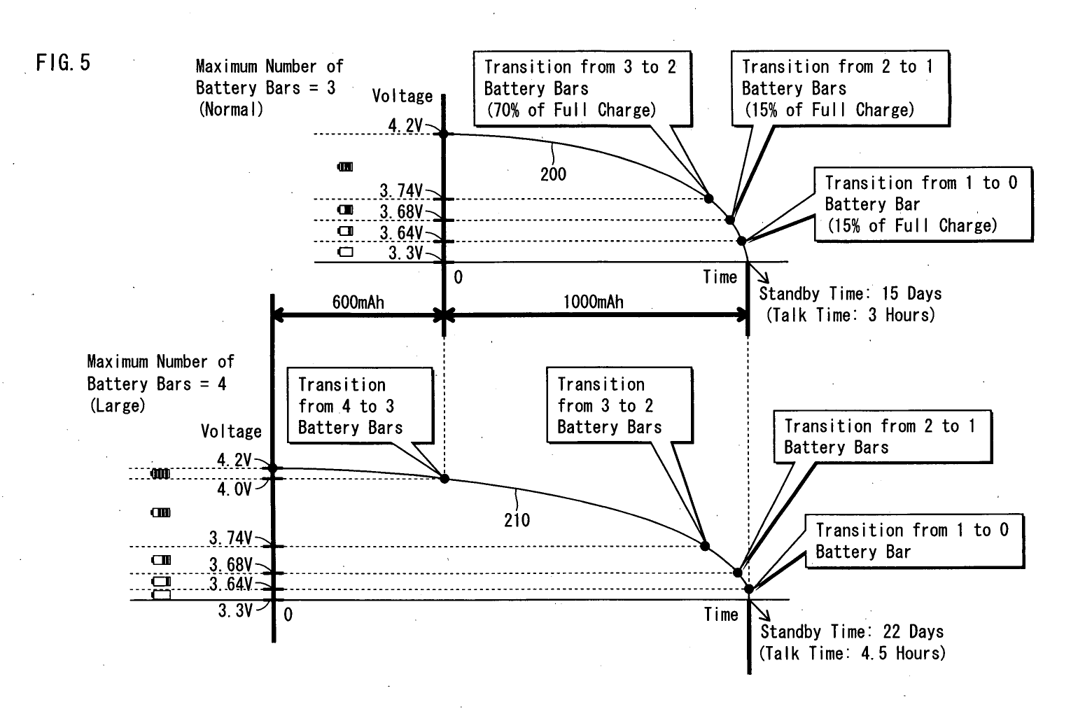

A graph 200 in FIG. 5 schematically shows the relation between the discharge time and the battery voltage of the battery 3, provided that the battery 3 is in a fully charged state at the beginning.

According to the above embodiment, as shown in FIG. 5, three battery bars are displayed for a time period corresponding to 70% of the entire discharge time starting from the fully-charged state. Note that the entire discharge time is a time period taken until the fully-charged battery 3 goes into an empty state. Since the battery voltage at the expiration of 70% of the entire discharge time is 3.74 volts, this voltage value is set as the threshold A21.

For a subsequent time period corresponding to 15% of the entire discharge time, two battery bars are displayed. Since the battery voltage at the expiration of 15% of the entire discharge time is 3.68 volts, this voltage value is set as the threshold A22.

For a subsequent time period corresponding to another 15% of the entire discharge time, one battery bar is displayed. Since the battery voltage at the expiration of 15% of the entire discharge time is 3.64 volts, this voltage value is determined as the threshold A23.

For a subsequent period that is extremely short relative to the entire discharge time, no battery bars are displayed.

A graph 210 in FIG. 5 schematically shows the relation between the discharge time and the battery voltage of the battery 4, provided that the battery 4 is in a fully charged state at the beginning.

In the case where the battery 4 is in use, four battery bars are displayed first. The time period for which four battery bars are displayed is set to be equal to a time period during which the extra amount of chargeable capacity corresponding to the difference between the batteries 3 and 4 is discharged. More specifically, four battery bars are displayed during the time the battery voltage falls within a range of 4.0 volts and 4.2 volts, exclusive of 4.2 volts.

In addition, in the case where the battery 4 is in use, three battery bars are displayed for a time period equal to the time period for which three battery bars are displayed in the case of the battery 3. More specifically, three battery bars are displayed during the time the battery voltage falls within a range of 3.74 volts to 4.0 volts, exclusive of 4.0 volts.

Similarly, in the case where the battery 4 is in use, two battery bars are displayed for a time period equal to the time period for which two battery bars are displayed in the case of the battery 3. More specifically, two battery bars are displayed during the time the battery voltage falls within a range of 3.68 volts to 3.74 volts, exclusive of 3.74 volts.

Similarly, in the case where the battery 4 is in use, one battery bar is displayed for a time period equal to the time period for which one battery bar is displayed in the case of the battery 3. More specifically, one battery bar is displayed during the time the battery voltage falls within a range of 3.64 volts and 3.68 volts, exclusive of 3.68 volts.

With the setting shown in FIG. 5, in the case where the battery 3 is in use, three battery bars are displayed until the expiration of a time period corresponding to 70% of the entire discharge time starting from the fully-charged state. Note that the entire discharge time is a time period taken until the fully-charged state battery 3 goes into an empty state. Subsequently, two battery bars are displayed until the expiration of a time period corresponding to 15% of the entire discharge time. Subsequently, one battery bar is displayed until the expiration of a time period corresponding to another 15% of the entire discharge time. After a short period for which no battery bars are displayed, the battery becomes exhausted. As above, the time period for which three battery bars are displayed is set to be longer than the other time periods during which different numbers of battery bars other than three are displayed. Such setting is made in order to achieve psychological effect of giving the user an impression that the battery is lasting long.

In addition, regardless of whether the battery 3 or 4 is in use, the time periods for which three battery bars are displayed for the respective batteries are equal. The same holds regarding the time periods for which two battery bars are displayed and also regarding the time periods for which one battery bar is displayed.

Consequently, once three or less battery bars are displayed, the user is allowed to know the time remaining before the battery becomes exhausted, without the need to distinguish which of the batteries 3 and 4 is installed.

Next, the following describes the threshold setting according to a modification.

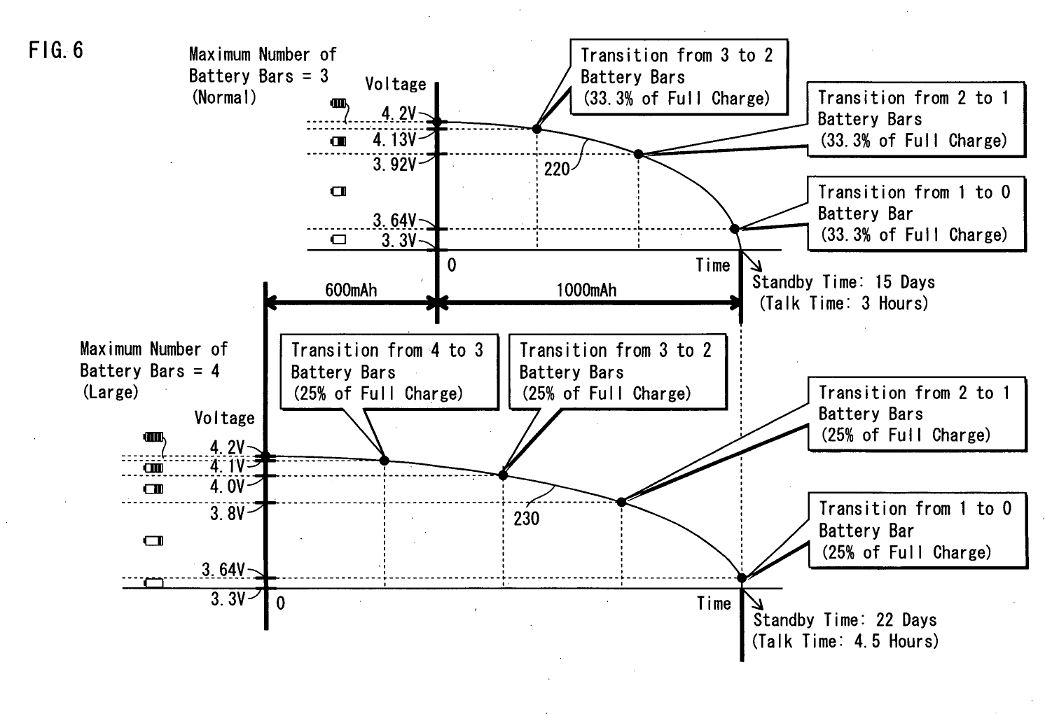

A graph 220 in FIG. 6 schematically shows the relation between the discharge time and the battery voltage of the battery 3 according to the modification, provided that the battery 3 is in a fully charged state at the beginning.

According to the modification, the thresholds are set so that the time periods during which three, two, and one battery bars are displayed become all substantially equal, provided that the battery 3 is in a fully charged state at the beginning.

A graph 230 in FIG. 6 schematically shows the relation between the discharge time and the battery voltage of the battery 4 according to the modification, provided that the battery 4 is in a fully charged state at the beginning.

According to the modification, the thresholds are set so that the time periods during which four, three, two, and one battery bars are displayed become all substantially equal, provided that the battery 4 is in a fully charged state at the beginning.

As described above, the modification shown in FIG. 6 is different from the embodiment shown in FIG. 5 in that the time period taken before display of any one battery bar is turned off is substantially equal. Thus, the user of the mobile phone according to the modification is allowed to know the remaining charge of the installed battery more accurately as compared with the setting shown in FIG. 5.

Note that the respective thresholds described above are set, assuming that the mobile phone consumes constant power throughout the respective time periods during which four, three, two, one and no battery bars are displayed.

### (2) Modification of Battery Icon Display

FIG. 7A shows an example of the battery icon displayed on the display unit 25 in the case where the battery 3, which is a normal battery, is installed in the main body 2.

The battery icon 301 corresponding to a normal battery encloses a space that is large enough for displaying three battery bars, and as many battery bars as the value of the variable i are displayed.

For example, when the variable i holds the value “3”, three battery bars, namely the battery bars 311, 312, and 313 are displayed. When the variable i holds the value “2”, two battery bars, namely the battery bars 312 and 313 are displayed but the battery bar 311 is not displayed. Instead of the battery bar 311, a space that is large enough to display the battery bar 311 is left blank in the battery icon 301.

Suppose that the battery 3 installed on the main body 2 is replaced with the battery 4, which is a large battery. Upon the battery replacement, the display unit 25 turns off display of the battery icon 301 and instead displays the battery icon 302 shown in FIG. 7B, according to the instructions given from the display generating unit 19.

The battery icon 302 corresponding to a large battery encloses a space that is large enough for displaying four battery bars, and as many battery bars as the value of the variable i are displayed correspondingly to the battery voltage.

When, for example, the variable i holds the value “4”, four battery bars, namely the battery bars 321, 322, 323, and 324, are displayed. When the variable i holds the value “3”, three battery bars, namely the battery bars 322, 323, and 324 are displayed but the battery bar 321 is not displayed. Instead of the battery bar 321, a space that is large enough to display the battery bar 321 is left blank in the battery icon 302.

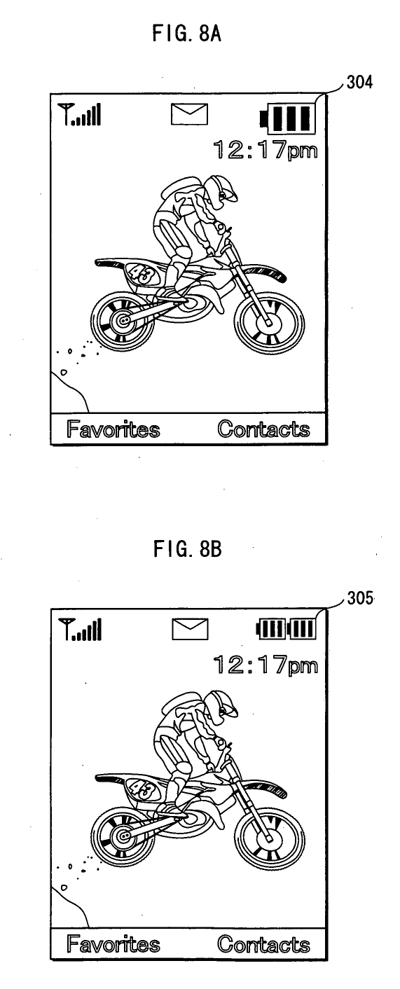

Alternatively, the display unit 25 may display either of battery icons 304 and 305 shown in FIGS. 8A and 8B.

Note that the battery icons 304 and 305 are both examples of battery icons to be displayed when the battery 4 is installed.

The battery icon 304 shown in FIG. 8A is composed of three battery bars which is equal to the number of battery bars used in the battery icon for a normal battery. Yet, each battery bar in the battery icon for a large battery is larger in display size than each battery bar in the battery icon for a normal battery. This difference in display size visually indicates to the user that a large battery is currently installed in the mobile phone.

The battery icon 305 shown in FIG. 8B is composed of two icons each of which is a graphical representation of a battery in order to visually indicate to the user that a large battery is currently installed on the mobile phone.

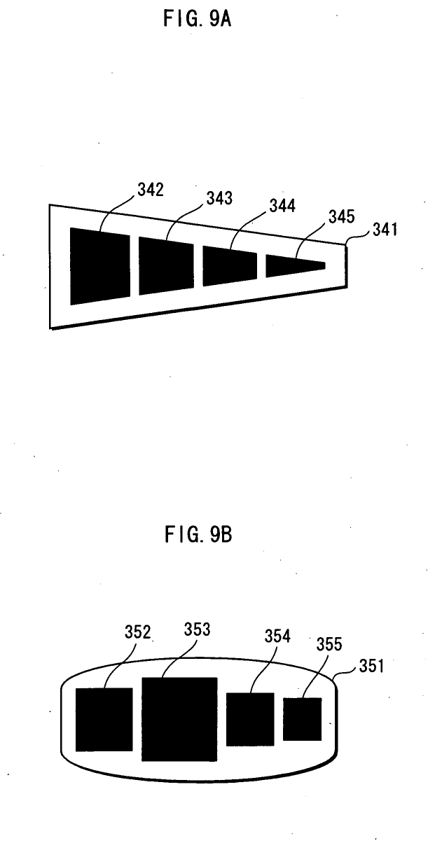

Alternatively, the display unit 25 may display either of battery icons 341 and 351 shown in FIGS. 9A and 9B, respectively. Note that the battery icons 304 and 305 are both examples of battery icons to be displayed when a large battery is installed.

The battery icon 341 shown in FIG. 9A and the battery icon 351 shown in FIG. 9B are both composed of four battery bars. The four battery bars are mutually different in shape and area size.

More specifically, the area size of each battery bar mutually differs correspondingly to the amount of battery charge represented by the battery bar.

As shown in FIG. 9A, the battery icon 341 is composed of four battery bars 342, 343, 344, and 345. The battery bar 342 is largest in area size, followed by the battery bars 343, 344, and 345 in the stated order.

As shown in FIG. 9B, the battery bar 353 is largest in area size, followed by the battery bars 352, 354, and 355 in the stated order.

Note that the order in which display of the battery bars is turned off is the same as a common mobile phone. That is, display of the battery bars is turned off one by one from the left to the right as viewed in the figures.

More specifically, in the example shown in FIG. 9B, display of the battery bars are turned off from the left to right and thus in the order of the battery bars 352, 353, 354, and 355.

(3) According to the above embodiment, the remaining charge of the battery is displayed using one of the battery icons. Alternatively, however, any image other than such an icon may be used.

(4) According to the above embodiment, there are two types of batteries, namely the battery 4, which is a large battery, and the battery 3, which is a normal battery. It should be appreciated, however, that the number of battery types is not limited to two and may be three or more.

(5) The present invention may be practiced as the method described above. Further, the present invention may be embodied as a computer program for causing a computer to execute the method. Still further, the present invention may be embodied as a digital signal representing the computer program.

The present invention may be practiced as a computer-readable recording medium storing the computer program or digital signal mentioned above. Examples of compute-readable recording media include a flexible disk, hard disk, CD-ROM, MO, DVD, DVD-ROM, DVD-RAM, BD (Blu-ray Disc), and semiconductor memory. Still further, the present invention may be embodied as the computer program or digital signal stored on such a recording medium.

(6) The present invention may be practiced as any combination of the above-described embodiment and modifications.

### (7) Correspondence Between Embodiment and Appended Claims

The judging unit recited in the claims is equivalent to the battery-type judging unit 23 described in the embodiment and/or modifications. The display control unit recited in the claims is equivalent to a combination of the judging unit 20, the threshold setting unit 24, and the display generating unit 19 described in the embodiment and/or modifications. The measuring unit recited in the claims is equivalent to the voltage measuring unit 22 described in the embodiment and/or modifications. The storage unit recited in the claims is equivalent to the storage unit 18 described in the embodiment and/or modifications. The display unit recited in the claims is equivalent to the display unit 25 described in the embodiment and/or modifications.

The image components recited in the claims to indicate the remaining charge of the battery are equivalent to the battery bars described in the embodiment and/or modifications.

The icon recited in the claims is equivalent to the battery icons and the battery bars described in the embodiment and/or modifications. Each battery icon is composed to include battery bars.

The other of the two types of the batteries recited in the claims is equivalent to the large battery described in the embodiment and/or modifications. The icon composed of two icons to indicate the remaining charge recited in the claims is equivalent to the battery icon 305 shown in FIG. 8B.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

What is claimed is:

1. An information processing terminal that displays an icon indicating a remaining charge of a battery installed therein, the information processing terminal comprising:
a judging unit operable to judge a type of the battery installed, out of a plurality of types of batteries differing in chargeable capacity; and
a display control unit operable to cause a display unit to display the icon for the battery installed, the icon visually representing the difference in chargeable capacity among the plurality of types of batteries.

2. The information processing terminal according to claim 1, further comprising:
a measuring unit operable to measure the remaining charge of the battery installed, wherein
judgment information indicates, for each of the plurality of types of batteries, information for dividing a range of output voltage into a different number of sections corresponding to the type of battery, and
the display control unit is operable to cause the display unit to display the icon that indicates the remaining charge measured by the measuring unit and that visually represents the number of sections corresponding, based on the judgment information stored in a storage unit, to the type of the battery installed.

3. The information processing terminal according to claim 2, wherein
the judgment information includes one or more boundary values each indicating a boundary between adjacent sections,
a natural number n denotes a total number of the plurality of types of batteries,
a natural number j denotes a number smaller than the natural number n,
all of the boundary values for a j-th battery out of the n types of batteries in increasing order of chargeable capacity are included in the boundary values for a (j+1)-th battery, and
the boundary values for the (j+1)-th battery include, in addition to all of the boundary values for the j-th battery, one or more boundary values each larger than the largest one of the boundary values for the j-th battery.

4. The information processing terminal according to claim 2, wherein
the judgment information includes one or more boundary values each indicating a boundary between adjacent sections, and
on condition that power consumption remains constant throughout all of the sections, the boundary values are configured so that a time period taken in each section for a maximum voltage to be reduced to a minimum voltage as a result of discharge is all equal.

5. The information processing terminal according to claim 1, wherein
the icon is composed of a plurality of image components including at least one image component for indicating the remaining charge,
a natural number n denotes a total number of the plurality of types of batteries,
a natural number j denotes a number smaller than the natural number n,
the display control unit is operable to change the number of image components displayed for indicating the remaining charge, in response to change in the remaining charge, and
a maximum number of the image components used to display the icon for a (j+1)-th battery out of the n types of batteries in increasing order of chargeable capacity is larger than a maximum number of the image components used to display the icon for a j-th battery.

6. The information processing terminal according to claim 1, wherein
a natural number n denotes a total number of the plurality of types of batteries,
a natural number j denotes a number smaller than the natural number n, and
the display control unit is operable to cause the display unit to display the icon, so that the icon for a (j+1)-th battery out of the n types of batteries in increasing order of chargeable capacity is larger in display size than the icon for a j-th battery.

7. The information processing terminal according to claim 1, wherein
a natural number n denotes a total number of the plurality of types of batteries,
a natural number j denotes a number smaller than the natural number n,
the icon is composed of n icons, and
the display-control unit is operable to cause the display unit to display the icon composed of j icons out of the n icons to indicate the remaining charge of a j-th battery out of the n types of batteries in increasing order of chargeable capacity.

8. The information processing terminal according to claim 1, wherein
each of the plurality of types of batteries has a different one of a plurality of mechanisms, and
the judging unit is operable to judge the type of the battery installed, based on the difference between the respective mechanisms.

9. The information processing terminal according to claim 1, wherein
the number of the plurality of types of batteries is two.

10. The information processing terminal according to claim 1, wherein
the number of the plurality of types of batteries is two, and
the display control unit is operable to cause the display unit to display the icon composed of one icon to indicate the remaining charge of one of the two types of batteries, and to display the icon composed of two icons to indicate the remaining charge of the other of the two types of batteries.

11. The information processing terminal according to claim 1, further comprising:
a call unit operable to place a call to another information processing terminal; and
the display unit.

12. A display control method for displaying an icon indicating a remaining charge of a battery installed, the display control method comprising:
a judging step of judging a type of the battery installed, out of a plurality of types of batteries differing in chargeable capacity; and
displaying on a display unit the icon for the battery installed, the icon visually representing the difference in chargeable capacity among the plurality of types of batteries.
